(19) United States
(12) Patent Application Publication
(10) Pub. No.: US 2012/0064366 A1
(43) Pub. Date: Mar. 15, 2012

(54) HOUSING AND METHOD FOR MANUFACTURING HOUSING

(75) Inventors: HSIN-PEI CHANG, Tu-Cheng (TW); WEN-RONG CHEN, Tu-Cheng (TW); HUAN-WU CHIANG, Tu-Cheng (TW); CHENG-SHI CHEN, Tu-Cheng (TW); MAN-XI ZHANG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/966,031

(22) Filed: Dec. 13, 2010

(30) Foreign Application Priority Data
Sep. 10, 2010 (CN) 201010278449.6

(51) Int. Cl. B32B 15/04; C23C 14/34; B32B 15/20

(52) U.S. Cl. 428/654; 428/34.1; 204/192.15

(57) ABSTRACT

A housing includes a substrate, an aluminum layer deposited on the substrate, and an aluminum oxynitride layer deposited on the aluminum layer. The aluminum layer includes aluminum. The aluminum oxynitride layer includes aluminum, nitride, and oxygen. A method for manufacturing the housing comprises providing a substrate, depositing an aluminum layer on the substrate, and depositing an aluminum oxynitride layer on the aluminum layer.

### BACKGROUND

1. Technical Field

The disclosure generally relates to housings for electronic devices and method for manufacturing the housings.

2. Description of Related Art

With the development of wireless communication and information processing technology, portable electronic devices such as mobile telephones and electronic notebooks are now in widespread use. Aluminum alloy has good heat dissipation and can effectively shield electromagnetic interference so aluminum alloy are widely used to manufacture housings of the portable electronic devices. However, aluminum alloy has low corrosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 illustrates a cross-sectional view of an embodiment of a housing.

FIG. 2 is a schematic view of a magnetron sputtering coating machine for manufacturing the housing in FIG. 1.

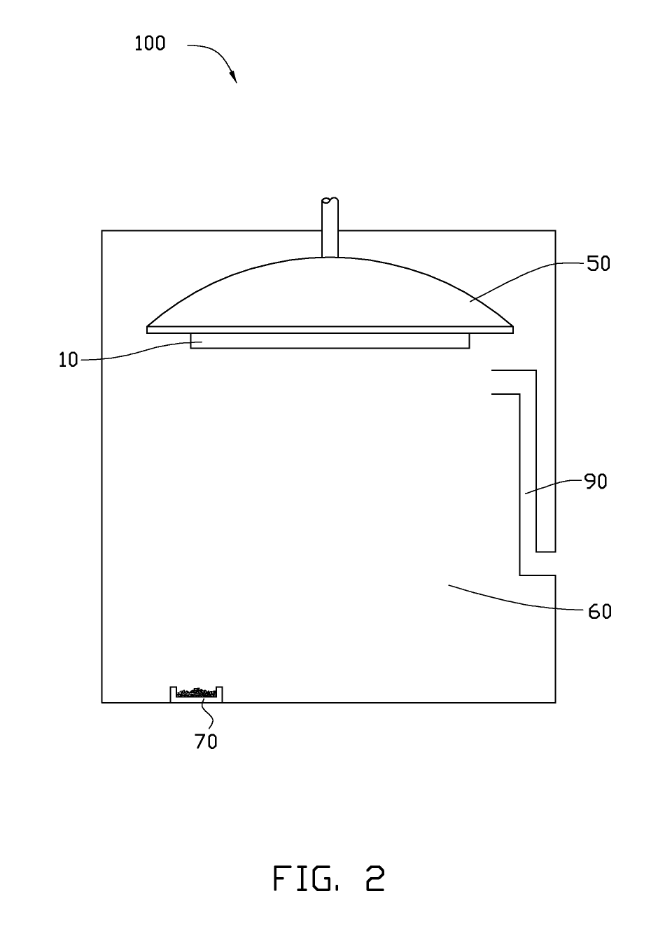

### DETAILED DESCRIPTION

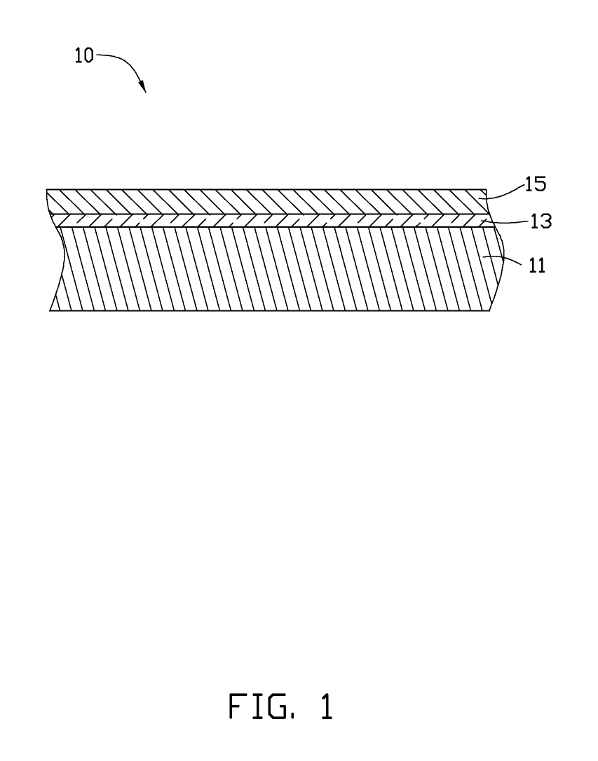

Referring to FIG. 1, a housing 10 includes a substrate 11, an aluminum layer 13 deposited on the substrate 11, and an aluminum oxynitride (AlNO) layer 15. The housing 10 may be for an electronic device. The substrate 11 may be made of aluminum alloy. The aluminum layer 13 is composed of aluminum. The aluminum layer 13 has a thickness ranging from about 200 nanometer (nm) to about 700 nm. The AlNO layer has a thickness ranging from about 0.2 micrometer (um) to about 0.5 um. The aluminum layer 13 and the AlNO layer 15 may be deposited by magnetron sputtering process or cathodic arc deposition.

A method for manufacturing the housing 10 includes the following steps.

Step 1 is providing the substrate 11. The substrate 11 may be made of aluminum alloy and may be molded by a punching method.

Step 2 is pretreating the substrate 11. First, the substrate 11 is washed with a solution (e.g., alcohol or acetone) in an ultrasonic cleaner to remove grease, dirt, and/or impurities. The substrate 11 is then dried. Finally, the substrate 11 is cleaned by argon plasma cleaning. The substrate 11 is retained on a rotating bracket 50 in a vacuum chamber 60 of a magnetron sputtering process coating machine 100. The vacuum level of the vacuum chamber 60 is adjusted to about 8.0×10⁻³Pa. Pure argon is pumped into the vacuum chamber 60 at a flux of about 300 Standard Cubic Centimeters per Minute (sccm) to about 600 sccm from a gas inlet 90. A bias voltage is applied to the substrate 11 in a range from about −300 volts to about −800 volts for about 3 minutes to about 10 minutes. The substrate 11 is washed by argon plasma to further remove the grease or dirt. Thus, the binding force between the substrate 11 and the aluminum layer 13 is enhanced.

Step 3 is depositing the aluminum layer 13 on the substrate 11. The temperature in the vacuum chamber 60 is adjusted to about 50° C. to about 130° C. Argon is pumped into the vacuum chamber 60 at a flux from about 130 sccm to about 300 sccm from the gas inlet 90. The speed of the rotating bracket 50 is adjusted to about 0.5 revolution per minute (rpm) to about 3 rpm. An aluminum target 70 is evaporated at a power from about 5 kw to about 10 kw. A bias voltage applied to the substrate 11 is in a range from about −50 volts to about −300 volts for a time of about 20 min to about 60 min, to deposit the aluminum layer 13 on the substrate 11.

Step 4 is depositing the AlNO layer 15 on the aluminum layer 13. The temperature in the vacuum chamber 60 is adjusted to about 50° C. to about 130° C. Nitrogen is pumped into the vacuum chamber 60 at a flux from about 10 sccm to about 120 sccm and oxygen is pumped into the vacuum chamber at a flux from about 10 sccm to about 60 sccm from the gas inlet 90. The speed of the rotating bracket is adjusted to about 0.5 rpm to about 3 rpm. The aluminum target 70 is evaporated at a power from about 5 kw to about 10 kw. A bias voltage is applied to the substrate 11 in a range from about −50 volts to about −300 volts for about 20 minutes to about 60 minutes, to deposit the AlNO layer 15 on the aluminum layer 13. During this stage, the aluminum, the nitrogen, and the oxygen react to form an aluminum (nitrogen, oxygen) solid solution phase, an aluminum-nitrogen phase, and an Al₂O₃ phase. The aluminum (nitrogen, oxygen) solid solution phase, aluminum-nitrogen phase, and Al₂O₃ phase can prevent columnar crystal from forming in the AlNO layer 15, thereby improving the compactness of the AlNO layer 15. Thus, the corrosion resistance of the housing 10 can be improved. Additionally, the aluminum layer 13 can improve the binding force between the AlNO layer 15 and the substrate 11. Furthermore, the aluminum (nitrogen, oxygen) solid solution phase, aluminum-nitrogen phase and Al₂O₃ phase can improve the abrasion resistance of the housing 10.

Depending on the embodiment, certain of the steps described below may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

It is to be understood, however, that even through numerous characteristics and advantages of the disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate;
an aluminum layer deposited on the substrate; and
an aluminum oxynitride layer deposited on the aluminum layer.

2. The housing as claimed in claim 1, wherein the aluminum layer and the aluminum oxynitride layer are both deposited by magnetron sputtering process.

3. The housing as claimed in claim 1, wherein the substrate is made of aluminum alloy.

4. The housing as claimed in claim 1, wherein the aluminum layer has a thickness ranging from about 200 nanometers to about 700 nanometers.

5. The housing as claimed in claim 1, wherein the aluminum oxynitride layer has a thickness ranging from about 0.2 micrometer to about 0.5 micrometer.

6. The housing as claimed in claim 1, wherein the aluminum oxynitride layer comprises aluminum (nitrogen, oxygen) solid solution phase, aluminum-nitrogen phase, and Al2O3 phase.

7. A method for manufacturing a housing, the method comprising:
providing a substrate made of aluminum alloy in a vacuum chamber;
depositing an aluminum layer on the substrate, wherein the aluminum layer is deposited on the substrate with an aluminum target by magnetron sputtering process; and
depositing an aluminum oxynitride layer on the aluminum layer, wherein the aluminum oxynitride layer is deposited on the aluminum layer with the aluminum target using nitrogen and oxygen as reaction gas by magnetron sputtering process, and the aluminum oxynitride layer comprising aluminum (nitrogen, oxygen) solid solution phase, aluminum-nitrogen phase, and Al2O3 phase.

8. The method of claim 7, wherein during depositing the aluminum layer on the substrate, the temperature in the vacuum chamber is about 50° C. to about 130° C., argon is pumped into the vacuum chamber at a flux from about 130 sccm to about 300 sccm, the aluminum target is evaporated at a power from about 5 kw to about 10 kw, and a bias voltage is applied to the substrate 11 in a range from about −50 volts to about −300 volts for about 20 minutes to about 60 minutes, to deposit the aluminum layer on the substrate.

9. The method of claim 7, wherein during depositing the aluminum oxynitride layer on the aluminum layer, the temperature in the vacuum chamber is about 50° C. to about 130° C., the nitrogen is pumped into the vacuum chamber at a flux from about 10 sccm to about 120 sccm, the oxygen is pumped into the vacuum chamber at a flux from about 10 sccm to about 60 sccm, the aluminum target is evaporated at a power from about 5 kw to about 10 kw, and a bias voltage is applied to the substrate 11 in a range from about −50 volts to about −300 volts for about 20 minutes to about 60 minutes, to deposit the aluminum oxynitride layer on the aluminum layer.

10. The method of claim 7, further comprising pretreating the substrate after depositing the aluminum layer on the substrate and before depositing the aluminum oxynitride layer on the aluminum layer; pretreating the substrate comprises washing the substrate with a solution in an ultrasonic cleaner, to remove grease, dirt, and/or impurities.

11. The method of claim 10, wherein pretreating the substrate further comprises drying the substrate after washing the substrate.

12. The method of claim 11, wherein pretreating the substrate further comprises cleaning the substrate by argon plasma cleaning after drying the substrate.

13. The method of claim 12, wherein cleaning the substrate by argon plasma cleaning comprises retaining the substrate on a rotating bracket in a vacuum chamber of a magnetron sputtering process coating machine in the vacuum chamber at 8.0×10⁻³Pa, pumping pure argon into the vacuum chamber at a flux of about 300 sccm to about 600 sccm, and applying a bias voltage to the substrate in a range from about −300 volts to about −800 volts for about 3 minutes to about 10 minutes.
